(19) United States
(12) Patent Application Publication
(10) Pub. No.: US 2018/0208766 A1
(43) Pub. Date: Jul. 26, 2018

(54) POLYAMIC ACID SOLUTION COMPOSITION AND POLYIMIDE FILM

(71) Applicant: UBE INDUSTRIES, LTD., Ube-shi (JP)

(72) Inventors: Tomonori NAKAYAMA, Ube-shi (JP); Takeshige NAKAYAMA, Ube-shi (JP); Naoki KITAYAMA, Ube-shi (JP)

(21) Appl. No.: 15/744,520

(22) PCT Filed: Jul. 15, 2016
(86) PCT No.: PCT/JP2016/071011

§ 371 Date: Jan. 12, 2018

(30) Foreign Application Priority Data
Jul. 16, 2015 (JP) 2015-141957

(51) Int. Cl. C08L 79/08; H05K 1/03

(52) U.S. Cl. CPC C08L 79/08; C08L 2201/56; C08L 2203/16; H05K 1/03

(57) ABSTRACT

A polyimide film including a polyimide obtained by polymerizing a tetracarboxylic acid component and a diamine component. The tetracarboxylic acid component consists of one or more tetracarboxylic dianhydride (a₁), in which at least one of the bonds linking the two cyclic anhydride structures contained in the molecule is a freely rotatable bond and a phthalic anhydride structure is not contained therein, and one or more tetracarboxylic dianhydride (a₂) having an alicyclic structure, in which each of two cyclic anhydride structures shares at least one carbon-carbon bond with the alicyclic structure and a freely rotatable bond is not contained in the molecule; and the diamine component includes one or more diamine having a 9,9-diphenylfluorene structure in an amount of 5 to 50 mol %.

### TECHNICAL FIELD

The present invention relates to a polyamic acid solution composition, and a polyimide film.

### BACKGROUND ART

Conventionally, a glass substrate has been used in an electronic device such as a flat panel display comprising a liquid crystal display element or an organic EL display element. However, there is a problem that glass is fragile due to insufficient strength when it is thinned down to be light-weight, and it also lacks flexibility, and therefore it is difficult to use glass as a flexible substrate. Accordingly, studies have been also conducted to use a resin material which is easy to be light-weight, thinner and flexible, for example, a polyimide film as an alternative material to glass, and various polyimides have been proposed (for example, Patent Literatures 1 to 3, etc.).

### CITATION LIST

### Patent Literature

Patent Literature 1: JP-A-2007-231224
Patent Literature 2: WO2013/179727A1
Patent Literature 3: WO2014/162733A1

### SUMMARY OF INVENTION

### Technical Problem

As for a display device, an image displayed by the element is observed through the substrate, and therefore a substrate for a display needs to have a high optical transparency and a small retardation in the thickness direction (Rth). As for a polyimide film, however, heat resistance, or mechanical properties such as flexibility and toughness are decreased when these optical properties are improved, and it has been difficult to achieve both these properties.

An object of the present invention is to provide a polyimide film which has a high optical transparency and a small retardation in the thickness direction, and also has excellent heat resistance, and mechanical properties such as flexibility and toughness; and a polyamic acid solution composition from which such a polyimide film may be obtained.

### Solution to Problem

The present invention relates to the following items.

1. A polyamic acid solution composition, comprising a polyamic acid obtained by reacting a tetracarboxylic acid component and a diamine component, and a solvent, wherein

the tetracarboxylic acid component consists of one or more tetracarboxylic dianhydride (a₁), wherein at least one of the bonds linking the two cyclic anhydride structures contained in the molecule is a freely rotatable bond and a phthalic anhydride structure is not contained therein, and one or more tetracarboxylic dianhydride (a₂) having an alicyclic structure, wherein each of two cyclic anhydride structures shares at least one carbon-carbon bond with the alicyclic structure and a freely rotatable bond is not contained in the molecule; and

the diamine component comprises one or more diamine having a 9,9-diphenylfluorene structure in an amount of 5 to 50 mol %.

2. The polyamic acid solution composition as described in “1” above, wherein the tetracarboxylic dianhydride (a₁) has 8 to 50 carbon atoms, and the tetracarboxylic dianhydride (a₂) has 8 to 30 carbon atoms.
3. The polyamic acid solution composition as described in “1” or “2” above, wherein the tetracarboxylic dianhydride (a₁) is a compound selected from 1,2,3,4-butane tetracarboxylic dianhydride, 4-(2,5-dioxotetrahydrofuran-3-yl)-1,2,3,4-tetrahydronaphthalene-1,2-dicarboxylic anhydride, dicyclohexyl-3,3′,4,4′-tetracarboxylic dianhydride, N,N′-(1,4-phenylene)bis(1,3-dioxooctahydroisobenzofuran-5-carboxyamide), and N,N′-(oxybis(1,4-phenylene))bis(1,3-dioxooctahydroisobenzofuran-5-carboxyamide).
4. The polyamic acid solution composition as described in any one of “1” to “3” above, wherein the tetracarboxylic dianhydride (a₂) is a compound selected from 1,2,3,4-cyclobutane tetracarboxylic dianhydride, 1,2,4,5-cyclohexane tetracarboxylic dianhydride, norbornane-2-spiro-α-cyclopentanone-α′-spiro-2″-norbornane-5,5″,6,6″-tetracarboxylic dianhydride, and decahydro-1,4:5,8-dimethanonaphthalene-2,3,6,7-tetracarboxylic dianhydride.
5. A method for producing a flexible device, comprising steps of

applying the polyamic acid solution composition as described in any one of “1” to “4” above on a carrier substrate, and then heating the composition to form a polyimide film on the carrier substrate;

forming a circuit on the polyimide film; and

peeling the polyimide film having the circuit formed on the surface from the carrier substrate.

6. A polyimide film consisting essentially of a polyimide obtained by polymerizing a tetracarboxylic acid component and a diamine component, wherein

the tetracarboxylic acid component consists of one or more tetracarboxylic dianhydride (a₁), wherein at least one of the bonds linking the two cyclic anhydride structures contained in the molecule is a freely rotatable bond and a phthalic anhydride structure is not contained therein, and one or more tetracarboxylic dianhydride (a₂) having an alicyclic structure, wherein each of two cyclic anhydride structures shares at least one carbon-carbon bond with the alicyclic structure and a freely rotatable bond is not contained in the molecule; and

the diamine component comprises one or more diamine having a 9,9-diphenylfluorene structure in an amount of 5 to 50 mol %.

7. The polyimide film as described in “6” above, wherein the tetracarboxylic dianhydride (a₁) has 8 to 50 carbon atoms, and the tetracarboxylic dianhydride (a₂) has 8 to 30 carbon atoms.
8. The polyimide film as described in “6” or “7” above, wherein the tetracarboxylic dianhydride (a₁) is a compound selected from 1,2,3,4-butane tetracarboxylic dianhydride, 4-(2,5-dioxotetrahydrofuran-3-yl)-1,2,3,4-tetrahydronaphthalene-1,2-dicarboxylic anhydride, dicyclohexyl-3,3′,4,4′-tetracarboxylic dianhydride, N,N′-(1,4-phenylene)bis(1,3-dioxooctahydroisobenzofuran-5-carboxyamide), and N,N′-(oxybis(1,4-phenylene))bis(1,3-dioxooctahydroisobenzofuran-5-carboxyamide).
9. The polyimide film as described in any one of “6” to “8” above, wherein the tetracarboxylic dianhydride (a₂) is a compound selected from 1,2,3,4-cyclobutane tetracarboxylic dianhydride, 1,2,4,5-cyclohexane tetracarboxylic dianhydride, norbornane-2-spiro-α-cyclopentanone-α′-spiro-2″-norbornane-5,5″,6,6″-tetracarboxylic dianhydride, and decahydro-1,4:5,8-dimethanonaphthalene-2,3,6,7-tetracarboxylic dianhydride.
10. The polyimide film as described in any one of “6” to “9” above, wherein

the glass-transition temperature (Tg) is 300° C. or higher;

the elongation is 10% or more; and

the retardation in the thickness direction (Rth) is 100 nm or less.

11. A flexible device, comprising the polyimide film as described in any one of “6” to “10” above as a substrate.

### Advantageous Effects of Invention

According to the present invention, a polyimide film which has a high optical transparency and a small retardation in the thickness direction, and also has excellent heat resistance, and mechanical properties such as flexibility and toughness may be obtained. The polyimide film may be suitably used as a substrate for a flexible device, for example, a display device such as a liquid crystal display, an organic EL display and an electronic paper, a light-receiving device such as a light-receiving element of a thin-film solar battery, or the like. According to the present invention, there may be also provided a polyamic acid solution composition from which a polyimide film having a high optical transparency and a small retardation in the thickness direction, and also having excellent heat resistance, and mechanical properties such as flexibility and toughness may be obtained.

### DESCRIPTION OF EMBODIMENTS

The polyamic acid solution composition of the present invention is the one in which a polyamic acid obtained by reacting a tetracarboxylic acid component comprising a compound selected from a specific group of compounds and a diamine component comprising a specific compound is dissolved in a solvent.

The tetracarboxylic acid component used in the present invention consists of at least two compounds, including one or more compound selected from the first group of compounds and one or more compound selected from the second group of compounds. The first group of compounds is a tetracarboxylic dianhydride (a₁), wherein at least one of the bonds linking the two cyclic anhydride structures contained in the molecule is a freely rotatable bond and a phthalic anhydride structure is not contained therein. Meanwhile, the second group of compounds is a tetracarboxylic dianhydride (a₂) having an alicyclic structure, wherein each of two cyclic anhydride structures shares at least one carbon-carbon bond with the alicyclic structure and a freely rotatable bond is not contained in the molecule.

The tetracarboxylic dianhydride (a₁) is characterized in that at least one of the one or more bonds linking the two cyclic anhydride structures contained in the molecule is a freely rotatable bond. The one in which each of the cyclic anhydride structures shares at least one carbon-carbon bond with the alicyclic structure and the bond linking the alicyclic structures is a freely rotatable bond is also included therein. The freely rotatable bond herein is not limited to a carbon-carbon bond, but includes a carbon-oxygen bond, a carbon-nitrogen bond, and the like. In other words, the tetracarboxylic dianhydride (a₁) refers to a tetracarboxylic dianhydride in which the positional relationship between the two cyclic anhydride structures is not fixed. The cyclic anhydride structure is, for example, a structure corresponding to succinic anhydride or glutaric anhydride. It is preferred that a phthalic anhydride structure is not contained in the molecule, although the form of the linking of the two cyclic anhydride structures is not particularly limited. In the case of a compound containing a phthalic anhydride structure, a reduction in optical transparency, or coloring may become a problem.

In addition, the tetracarboxylic dianhydride (a₁) preferably has 8 to 50 carbon atoms, more preferably 12 to 40 carbon atoms. When the number of carbon atoms is too large, the concentration of imide group in the molecular chain of the obtained polyimide is decreased, and therefore a problem with mechanical properties may arise.

Examples of the compound included in the tetracarboxylic dianhydride (a₁) include 1,2,3,4-butane tetracarboxylic dianhydride, 4-(2,5-dioxotetrahydrofuran-3-yl)-1,2,3,4-tetrahydronaphthalene-1,2-dicarboxylic anhydride, bicyclohexyl-3,3′,4,4′-tetracarboxylic dianhydride, bicyclohexyl-2,3,3′,4′-tetracarboxylic dianhydride, bicyclohexyl-2,2,3′,3′-tetracarboxylic dianhydride, 4,4′-methylenebis(cyclohexane-1,2-dicarboxylic) dianhydride, 4,4′-oxybis(cyclohexane-1,2-dicarboxylic) dianhydride, 4,4′-thiobis (cyclohexane-1,2-dicarboxylic) dianhydride, 4,4′-sulfonylbis(cyclohexane-1,2-dicarboxylic) dianhydride, 4,4′-(dimethylsilanediyl)bis(cyclohexane-1,2-dicarboxylic) dianhydride, 4,4′-(tetrafluoropropane-2,2-diyl)bis(cyclohexane-1,2-dicarboxylic) dianhydride, N,N′-(1,4-phenylene)bis(1,3-dioxooctahydroisobenzofuran-5-carboxyamide), N,N′-(oxybis(1,4-phenylene)) bis(1,3-dioxooctahydroisobenzofuran-5-carboxyamide), N,N′-(sulfonylbis(1,4-phenylene))bis(1,3-dioxooctahydroisobenzofuran-5-carboxyamide), and N,N′-(2,2′-bis(trifluoromethyl)-[1,1′-biphenyl]-4,4′-diyl)bis(1,3-dioxooctahydroisobenzofuran-5-carboxyamide).

In the present invention, among these compounds, a compound selected from the group consisting of 1,2,3,4-butane tetracarboxylic dianhydride, 4-(2,5-dioxotetrahydrofuran-3-yl)-1,2,3,4-tetrahydronaphthalene-1,2-dicarboxylic anhydride, dicyclohexyl-3,3′,4,4′-tetracarboxylic dianhydride, N,N′-(1,4-phenylene)bis(1,3-dioxooctahydroisobenzofuran-5-carboxyamide), and N,N′-(oxybis(1,4-phenylene))bis(1,3-dioxooctahydroisobenzofuran-5-carboxyamide) may be preferably used.

The tetracarboxylic dianhydride (a₂) is characterized in that a freely rotatable bond is not contained in the molecule. In other words, the tetracarboxylic dianhydride (a₂) refers to a tetracarboxylic dianhydride in which there is a restriction on the positional relationship between the two cyclic anhydride structures, or the positional relationship between the two cyclic anhydride structures is substantially fixed. Additionally, the tetracarboxylic dianhydride (a₂) is the one having an alicyclic structure, in which each of two cyclic anhydride structures shares at least one carbon-carbon bond with the alicyclic structure. The term “the cyclic anhydride structure shares at least one carbon-carbon bond with the alicyclic structure” herein means that it is a structure corresponding to cycloalkane dicarboxylic anhydride, for example.

In addition, the tetracarboxylic dianhydride (a₂) preferably has 8 to 30 carbon atoms, more preferably 8 to 25 carbon atoms. When the number of carbon atoms is too large, the concentration of imide group in the molecular chain of the obtained polyimide is decreased, and therefore a problem with mechanical properties may arise.

Examples of the compound included in the tetracarboxylic dianhydride (a₂) include 1,2,3,4-cyclobutane tetracarboxylic dianhydride, 1,2,3,4-cyclopentane tetracarboxylic dianhydride, 1,2,4,5-cyclohexane tetracarboxylic dianhydride, bicyclo[2,2,2]octane-2,3,5,6-tetracarboxylic dianhydride, bicyclo[2,2,2]oct-7-ene-2,3,5,6-tetracarboxylic dianhydride, norbornane-2-spiro-α-cyclopentanone-α′-spiro-2″-norbornane-5,5″,6,6″-tetracarboxylic dianhydride, decahydro-1,4:5,8-dimethanonaphthalene-2,3,6,7-tetracarboxylic dianhydride, and 1,2,4-tricarboxy-3-carboxymethyl cyclopentane dianhydride.

In the present invention, among these compounds, a compound selected from the group consisting of 1,2,3,4-cyclobutane tetracarboxylic dianhydride, 1,2,4,5-cyclohexane tetracarboxylic dianhydride, norbornane-2-spiro-α-cyclopentanone-α′-spiro-2″-norbornane-5,5″,6,6″-tetracarboxylic dianhydride, and decahydro-1,4:5,8-dimethanonaphthalene-2,3,6,7-tetracarboxylic dianhydride may be preferably used.

The ratio (molar ratio) of the tetracarboxylic dianhydride (a₁) to the tetracarboxylic dianhydride (a₂) is preferably, but not limited to, 5:95 to 95:5, more preferably 15:85 to 85:15, particularly preferably 20:80 to 80:20.

The diamine component used in the present invention comprises one or more diamine having a 9,9-diphenylfluorene structure in an amount of 5 to 50 mol %, preferably 10 to 50 mol %, more preferably 10 to 45 mol %, more preferably 15 to 45 mol %, particularly preferably 15 to 40 mol %. Examples of the diamine having a 9,9-diphenylfluorene structure include 9,9-bis(4-aminophenyl)fluorene, 9,9-bis(3-fluoro-4-aminophenyl)fluorene, 9,9-bis(3-methyl-4-aminophenyl)fluorene, and 9,9-bis[(4-aminophenoxy)phenyl]fluorene.

Examples of the diamine other than the diamine having a 9,9-diphenylfluorene structure to be used in the present invention include aromatic compounds such as p-phenylenediamine, m-phenylenediamine, 2,4-diaminotoluene, 2,5-diaminotoluene, m-tolidine, 4,4′-diaminodiphenylether, 3,4′-diaminodiphenylether, 3,3′-diaminodiphenylether, 4,4′-methylene dianiline, 1,3-bis(4-aminophenoxy)benzene, 1,4-bis(4-aminophenoxy)benzene, 1,3-bis(3-aminophenoxy)benzene, 4,4′-bis(4-aminophenoxy)biphenyl, 2,2-bis[4-(4-aminophenoxy)phenyl]propane, 4,4′-diaminobenzanilide, 2,2′-bis(trifluoromethyl)benzidine, 3,3′-bis(trifluoromethyl)benzidine, 2,2-bis(4-aminophenyl)hexafluoropropane, 2,2-bis[4-(4-aminophenoxy)phenyl]hexafluoropropane, 2,7-diaminofluorene, 4,4′-bis(3-aminophenoxy)biphenyl, bis(4-aminophenyl)sulfone, 3,3′-bis((aminophenoxy)phenyl)propane, 2,2′-bis(3-amino-4-hydroxyphenyl) hexafluoropropane, bis(4-(4-aminophenoxy) diphenyl)sulfone, bis(4-(3-aminophenoxy)diphenyl)sulfone, octafluorobenzidine, 3,3′-dimethoxy-4,4′-diaminobiphenyl, 3,3′-dichloro-4,4′-diaminobiphenyl, 3,3′-difluoro-4,4′-diaminobiphenyl, 4,4″-diamino-p-terphenyl, 5-amino-2-(4-aminophenyl)benzoimidazole, 2,4-bis(4-aminoanilino)-6-diphenylamino-1,3,5-triazine, 2,4-bis(4-aminoanilino)-6-anilino-1,3,5-triazine, 2,4-bis(3-aminoanilino)-6-anilino-1,3,5-triazine, 1,6-bis(4-aminophenoxy)naphthalene, 1,4-bis(4-aminophenoxy)naphthalene, and 3,3′-biphenyl-4,4′-bis(4-aminophenoxy)biphenyl.

In addition, examples thereof include alicyclic compounds such as 1,4-diaminocyclohexane, 1,3-bis(aminomethyl)cyclohexane, 1,4-bis(aminomethyl) cyclohexane, 4,4′-methylenebis(cyclohexylamine), bis(aminomethyl)norbornane, 1,4-diamino-2-methylcyclohexane, 1,4-diamino-2-ethylcyclohexane, 1,4-diamino-2-n-propylcyclohexane, 1,4-diamino-2-isopropylcyclohexane, 1,4-diamino-2-n-butylcyclohexane, 1,4-diamino-2-isobutylcyclohexane, 1,4-diamino-2-sec-butylcyclohexane, 1,4-diamino-2-tert-butylcyclohexane, 1,2-diaminocyclohexane, 1,3-diaminocyclobutane, 1,4-bis(aminomethyl)cyclohexane, 1,3-bis(aminomethyl)cyclohexane, diaminobicycloheptane, diaminomethylbicycloheptane, diaminooxybicycloheptane, diaminomethyloxybicycloheptane, isophoronediamine, diaminotricyclodecane, diaminomethyltricyclodecane, bis(aminocyclohexyl) methane, bis(aminocyclohexyl)isopropylidene, 6,6′-bis(3-aminophenoxy)-3,3,3′,3′-tetramethyl-1,1′-spirobiindane, and 6,6′-bis(4-aminophenoxy)-3,3,3′,3′-tetramethyl-1,1′-spirobiindane. These aromatic diamines and alicyclic diamines may be used alone, or may be used in combination of a plurality of compounds.

Among them, p-phenylenediamine, 1,3-bis(4-aminophenoxy)benzene, 1,4-bis(4-aminophenoxy)benzene, 1,3-bis(3-aminophenoxy)benzene, 4,4′-diaminodiphenylether, m-tolidine, 3,4′-diaminodiphenylether, 3,3′-diaminodiphenylether, 2,2-bis[4-(4-aminophenoxy)phenyl]propane, 4,4′-diaminobenzanilide, 2,2′-bis(trifluoromethyl)benzidine, 4,4′-bis(4-aminophenoxy)biphenyl, 4,4″-diamino-p-terphenyl, 5-amino-2-(4-aminophenyl)benzoimidazole, 2,4-bis(4-aminoanilino)-6-diphenylamino-1,3,5-triazine, 2,4-bis(4-aminoanilino)-6-anilino-1,3,5-triazine, 2,4-bis(3-aminoanilino)-6-anilino-1,3,5-triazine, 1,6-bis(4-aminophenoxy)naphthalene, 1,4-bis(4-aminophenoxy)naphthalene, 3,3′-biphenyl-4,4′-bis(4-aminophenoxy) biphenyl, 2,4-bis(3-aminoanilino)-6-anilino-1,3,5-triazine, and 1,4-diaminocyclohexane are preferred as the diamine other than the diamine having a 9,9-diphenylfluorene structure.

The polyamic acid used in the present invention may be obtained, in the form of a polyamic acid solution composition, by reacting a tetracarboxylic acid component and a diamine component in a solvent. In the reaction, the tetracarboxylic acid component and the diamine component are usually used in substantially equimolar amounts. Specifically, the molar ratio of the tetracarboxylic acid component to the diamine component [the tetracarboxylic acid component/the diamine component] is preferably about 0.90 to about 1.10, more preferably about 0.95 to about 1.05. The reaction is performed at a relatively low temperature, for example, at 100° C. or lower, preferably at 80° C. or lower, so as to suppress the imidization. It is usually preferred that the reaction temperature is 25° C. to 100° C., preferably 40° C. to 80° C., more preferably 50° C. to 80° C., and the reaction time is about 0.1 hours to about 24 hours, preferably about 2 hours to about 12 hours, although they are not limited thereto. When the reaction temperature and the reaction time are set within the ranges as described above, a solution composition of a polyamic acid having a high molecular weight may be obtained with good efficiency. The reaction is usually preferably performed in an inert gas atmosphere, preferably in a nitrogen gas atmosphere, although the reaction may be performed in an air atmosphere.

Examples of the solvent used in the production of the polyamic acid include, but not limited to, amide solvents such as N,N-dimethylformamide, N,N-dimethylacetamide, N,N-diethylacetamide, N-methylformamide, N,N-dimethylpropionamide, N,N-dimethylisobutylamide, N-methyl-2-pyrrolidone, N-ethyl-2-pyrrolidone and N-vinyl-2-pyrrolidone; cyclic ester solvents such as γ-butyrolactone, γ-valerolactone, δ-valerolactone, γ-caprolactone, ε-caprolactone and α-methyl-γ-butyrolactone; carbonate solvents such as ethylene carbonate and propylene carbonate; glycol solvents such as triethylene glycol; phenol solvents such as m-cresol, p-cresol, 3-chlorophenol and 4-chlorophenol; acetophenone, 1,3-dimethyl-2-imidazolidinone, sulfolane, dimethylsulfoxide, 1,4-dioxane, and tetramethylurea. The organic solvent to be used may be one, or may be a mixture of two or more solvents.

In the present invention, the logarithmic viscosity of the polyamic acid in a N,N-dimethylacetamide solution at a concentration of 0.5 g/dL at 30° C. is preferably 0.2 dL/g or more, preferably 0.4 dL/g or more, although the logarithmic viscosity is not limited thereto. When the logarithmic viscosity is 0.2 dL/g or more, the molecular weight of the polyamic acid, which is a polyimide precursor, is high, and therefore the obtained polyimide may have excellent mechanical strength and heat resistance.

The polyamic acid solution composition of the present invention comprises at least the polyamic acid as described above, and a solvent. The solvent is not particularly limited, on the condition that the polyamic acid can be dissolved therein, and examples thereof include the same as the solvent to be used in the production of the polyamic acid.

As for the polyamic acid solution composition of the present invention, the solid content based on the polyamic acid is preferably, but not limited to, 5 mass % to 45 mass %, more preferably 7 mass % to 40 mass %, more preferably 9 mass % to 30 mass %, relative to the total amount of the polyimide precursor and the solvent. When the solid content is lower than 5 mass %, the productivity and the handling in use may be reduced. When the solid content is higher than 45 mass %, the solution may lose the fluidity.

In view of the handling, the solution viscosity of the polyamic acid solution composition of the present invention at 30° C. is preferably, but not limited to, 1000 Pa-sec or lower, more preferably 0.1 Pa-sec to 500 Pa-sec, more preferably 0.1 Pa-sec to 300 Pa-sec, particularly preferably 0.1 Pa-sec to 200 Pa-sec. When the solution viscosity is higher than 1000 Pa-sec, the composition may lose the fluidity, and therefore it may be difficult to uniformly apply the composition on a support such as metal and glass. When the solution viscosity is lower than 0.1 Pa-sec, dripping, repelling, and the like may occur during the application of the composition on a support such as metal and glass, and it may be difficult to obtain a polyimide, or a polyimide film, a polyimide substrate for flexible devices, or the like, which have high quality.

The polyamic acid solution composition of the present invention may comprise an imidization catalyst. Examples of the imidization catalyst include aliphatic tertiary amines, aromatic tertiary amines, and heterocyclic tertiary amines. Among them, nitrogen-containing heterocyclic compounds such as imidazole compounds, benzimidazole compounds, quinoline compounds, isoquinoline compounds, pyridine, and picoline are preferred. The imidization catalyst may be used alone, or may be used in combination of two or more types. The amount of the imidization catalyst to be added is preferably within the range of 0.02 mol to 1 mol, more preferably 0.05 mol to 0.5 mol, relative to 1 mol of the tetracarboxylic acid component or the diamine component constituting the polyamic acid contained in the polyamic acid solution composition.

The polyamic acid solution composition of the present invention may comprise an ultraviolet absorber. Examples of the ultraviolet absorber include benzotriazole ultraviolet absorbers, benzophenone ultraviolet absorbers, benzoate ultraviolet absorbers, triazine ultraviolet absorbers, and hindered amine ultraviolet absorbers. Among them, benzotriazole ultraviolet absorbers, and triazine ultraviolet absorbers are preferred, and benzotriazole ultraviolet absorbers are more preferred. The ultraviolet absorber may be used alone, or may be used in combination of two or more types. The amount of the ultraviolet absorber to be added is preferably 0.01 parts by mass to 5 parts by mass, more preferably 0.1 parts by mass to 4 parts by mass, particularly preferably 0.5 parts by mass to 2 parts by mass, relative to 100 parts by mass of the obtained polyimide. When the amount of the ultraviolet absorber is too large, the properties of the polyimide such as optical properties and heat resistance may be deteriorated, and haze may occur in the film.

The polyamic acid solution composition of the present invention may comprise silica. The silica is preferably the one having a particle size of 100 nm or less, more preferably 1 nm to 60 nm, particularly preferably 1 nm to 50 nm, more preferably 10 nm to 30 nm, wherein the particle size is measured by the dynamic light scattering method. The content of the silica is preferably 1 parts by mass to 100 parts by mass, more preferably 5 parts by mass to 90 parts by mass, particularly preferably 10 parts by mass to 90 parts by mass, relative to 100 parts by mass of the total amount of the tetracarboxylic acid component and the diamine component.

It is preferred that the silica in the form of a colloid solution in which colloidal silica is dispersed in an organic solvent is added to, and mixed with the polyamic acid solution. Examples of the solvent of the colloidal silica include, but not limited to, N,N-dimethylacetamide (DMAc), N,N-dimethylformamide (DMF), propylene glycol monomethyl ether acetate (PMA), ethylene glycol mono-n-propyl ether (NPC), ethylene glycol (EG), isopropanol (IPA), methanol, methyl ethyl ketone, methyl isobutyl ketone, xylene, n-butanol, and propylene glycol monomethyl ether. The solvent of the colloidal silica is preferably selected depending on the solvent of the polyamic acid solution so as to achieve desired properties, and is usually preferably a solvent having a high compatibility with the polyamic acid solution. The organic solvent to be used may be one, or may be a mixture of two or more solvents.

The polyamic acid solution composition of the present invention may also comprise an additive component other than those as described above.

A polyimide solution composition may be prepared by heating the polyamic acid solution composition of the present invention, to imidize (dehydration and ring-closing) the polyamic acid and form a polyimide. The heating condition is not particularly limited, as long as it is a condition which allows the imidization to be completed, and the imidization may be completed, for example, by heating the composition at 100° C. to 250° C. for 1 hour to 10 hours. Depending on the solubility of the obtained polyimide in the solvent, however, it may be difficult to prepare a polyimide solution composition. In addition, a polyimide solution composition may also be prepared by pouring the obtained polyimide solution composition into a poor solvent such as alcohol to precipitate the polyimide resin, and separating it, and then redissolving the polyimide resin in a solvent. As the solvent in which the polyimide resin is redissolved, the solvent to be used in the production of the polyamic acid as described above may be used. And then, the polyimide film of the present invention may be obtained by applying the obtained polyimide solution composition on a substrate, and then subjecting the composition to heat treatment to remove the solvent therefrom. The heat treatment condition is not particularly limited, and may be appropriately selected.

The polyimide film of the present invention may also be obtained by applying the polyamic acid solution composition of the present invention on a substrate, and then removing the solvent therefrom and concurrently imidizing (dehydrating and ring-closing) the polyamic acid by heat treatment. The heat treatment condition is not particularly limited, but it is preferred that the composition is dried in the temperature range of 50° C. to 150° C., and then heated at the highest heating temperature of 300° C. to 500° C., preferably 350° C. to 450° C. The heat treatment is usually preferably carried out in an inert gas atmosphere, preferably in a nitrogen gas atmosphere, although the heat treatment may be carried out in an air atmosphere.

The polyimide film of the present invention is a polyimide film consisting essentially of a polyimide obtained by polymerizing a tetracarboxylic acid component and a diamine component as described above, that is, a tetracarboxylic acid component consisting of one or more tetracarboxylic dianhydride (a₁), wherein at least one of the bonds linking the two cyclic anhydride structures contained in the molecule is a freely rotatable bond and a phthalic anhydride structure is not contained therein, and one or more tetracarboxylic dianhydride (a₂) having an alicyclic structure, wherein each of two cyclic anhydride structures shares at least one carbon-carbon bond with the alicyclic structure and a freely rotatable bond is not contained in the molecule, and a diamine component comprising one or more diamine having a 9,9-diphenylfluorene structure in an amount of 5 to 50 mol %. The preferred tetracarboxylic acid component and diamine component are also the same as the polyamic acid in the polyamic acid solution composition of the present invention as described above.

It is preferred that the polyimide film of the present invention has high transparency, and when the thickness is 10 μm, the light transmittance at a wavelength of 400 nm is preferably 70% or more, more preferably 75% or more, more preferably 80% or more, for example. In addition, it is preferred that the retardation in the thickness direction (Rth) is small, and when the thickness is 10 μm, it is preferably 100 nm or less, more preferably 50 nm or less, particularly preferably 30 nm or less, for example. The retardation in the thickness direction (Rth) is defined as the following, and usually is not a negative value.

Rth(nm)=[(nx+ny)/2−nz]×d

(nx, ny, and nz represent the X-axis, Y-axis, and Z-axis refractive indexes of the polyimide film, respectively; and d represents the thickness of the polyimide film. Herein, the X-axis is the direction exhibiting a maximum refractive index in the plane; the Y-axis is the direction orthogonal to the X-axis in the plane; and the Z-axis is the thickness direction orthogonal to these axes.)

It is also preferred that the polyimide film of the present invention has a high glass-transition temperature (Tg), and the glass-transition temperature (Tg) is preferably 300° C. or higher, preferably 320° C. or higher, more preferably 350° C. or higher, for example. In addition, it is preferred that the polyimide film of the present invention has an elongation of 10% or more, and has excellent flexibility and toughness.

As for the method for producing the flexible device of the present invention, a polyimide film is formed first by flow-casting and applying the polyamic acid solution composition on a carrier substrate, and then imidizing it by heat treatment. There is no limitation on the carrier substrate, but a glass substrate such as soda-lime glass, borosilicate glass, and alkali-free glass, or a metal substrate such as iron and stainless steel is generally used. The method for flow-casting the polyamic acid solution on a glass substrate is not particularly limited, and examples thereof include conventionally-known methods such as spin coating, screen printing, bar coating, and electro coating, for example. The heat treatment condition is not particularly limited, but it is preferred that the composition is dried in the temperature range of 50° C. to 150° C., and then treated at the highest heating temperature of 300° C. to 500° C., preferably 350° C. to 450° C.

The thickness of the formed polyimide film is desirably 1 μm to 20 μm. When the thickness is less than 1 μm, the polyimide film may not maintain an adequate mechanical strength, and therefore the polyimide film may not withstand stress and may be broken when it is used as a flexible device substrate, or the like. Meanwhile, when the thickness of the polyimide film is more than 20 μm and thicker, it may be difficult to achieve the thinning of the flexible device. The thickness of the polyimide resin film is more desirably 2 μm to 10 μm so as to achieve the further thinning, while maintaining an adequate resistance for the flexible device.

A circuit required for a display device such as a liquid crystal display, an organic EL display and an electronic paper, a light-receiving device such as a solar battery and a CMOS, or the like, for example, is formed on the polyimide film formed as described above. This step varies according to the type of the device. In the case where a TFT liquid crystal display device is produced, for example, an amorphous silicon TFT is formed on the polyimide film. The TFT comprises a gate metal layer, a silicon nitride gate dielectric layer, and an ITI pixel electrode. In addition, a structure required for the liquid crystal display may be formed thereon by a known method.

And then, the polyimide film having the circuit, or the like, formed on the surface is peeled from the carrier substrate. The peeling method is not particularly limited, and the peeling may be performed by irradiation with laser, or the like, from the carrier substrate side, for example. The flexible device of the present invention, which comprises the polyimide film as the substrate, may be thus obtained.

Examples of the flexible device in the present invention include display devices such as a liquid crystal display, an organic EL display and an electronic paper, and light-receiving devices such as a solar battery and a CMOS. The present invention is particularly suitable for the application to devices which are desired to be thinner and have flexibility.

### EXAMPLES

The present invention will be described in more detail below with reference to Examples. However, the present invention is not limited to the Examples as described below.

The abbreviations of the compounds used in the Examples as described below are as follows.
HTAC(PPD): N,N′-(1,4-phenylene)bis(1,3-dioxooctahydroisobenzofuran-5-carboxyamide)
H-BPDA: bicyclohexyl-3,3′,4,4′-tetracarboxylic dianhydride
CpODA: norbornane-2-spiro-α-cyclopentanone-α′-spiro-2″-norbornane-5,5″,6,6″-tetracarboxylic dianhydride
DNDA: decahydro-1,4:5,8-dimethanonaphthalene-2,3,6,7-tetracarboxylic dianhydride
H-PMDA: 1,2,4,5-cyclohexane tetracarboxylic dianhydride
CBDA: 1,2,3,4-cyclobutane tetracarboxylic dianhydride
BAFL: 9,9-bis(4-aminophenyl) fluorene
ODA: 4,4′-diaminodiphenyl ether
CHDA: 1,4-diaminocyclohexane
BAPB: 4,4′-bis(4-aminophenoxy)biphenyl
1,2-DMZ: 1,2-dimethylimidazole

The methods for measuring the properties, which were used in the Examples as described below, will be set forth below.

### (Solid Content)

The solid content of the polyamic acid solution was the value which was calculated by the following formula from the weight before drying W₁ and the weight after drying W₂, wherein the polyamic acid solution was dried at 350° C. for 30 minutes.

Solid content (wt %)=(W₂/W₁)×100

### (Light Transmittance)

The light transmittance at 365 nm and 400 nm of the polyimide film was measured using a spectrophotometer U-2910 (made by Hitachi High-Technologies Corporation).

### (Retardation in the Thickness Direction)

The retardation in the thickness direction Rth was measured at a measurement wavelength of 590 nm and an incidence angle of 40° using a retardation measuring apparatus KOBRA-WR (made by Oji Scientific Instruments Co., Ltd.).

### (Glass-Transition Temperature (Tg))

The polyimide film having a thickness of 10 μm was cut to a rectangle having a width of 4 mm, which was used as a test piece, and the test piece was heated to 400° C. at a distance between chucks of 15 mm, a load of 2 g and a temperature-increasing rate of 20° C./min using a TMA/SS6100 (made by SII Nanotechnology Inc.). The Tg was calculated from the inflection point of the obtained TMA curve.

### (Elongation)

The polyimide film having a thickness of about 10 μm was punched to the dumbbell shape of IEC-450 standard, which was used as a test piece, and the initial modulus of elasticity, and the elongation at break were measured at a distance between chucks of 30 mm and a tensile speed of 2 mm/min using a TENSILON made by Orientec Co., Ltd.

### Example 1

In a 500 mL (internal volume) glass reaction vessel equipped with a stirrer and a nitrogen-gas charging/discharging tube was placed 420 g of N-methyl-2-pyrrolidone as a solvent. Then 16.1910 g (0.0809 mol) of ODA, 12.0734 g (0.0347 mol) of BAFL, 11.0990 g (0.0289 mol) of CpODA and 40.5803 g (0.0866 mol) of HTAC(PPD) were added thereto, and the mixture was stirred at 50° C., to obtain a polyamic acid solution having a solid content of 15.17%.

The polyamic acid solution was applied on a glass plate as a substrate with a bar coater. The coating film was heated from 50° C. to 350° C. at a temperature-increasing rate of 10° C./min, and then heated at 350° C. for 5 minutes in a nitrogen atmosphere, to form a polyimide film having a thickness of 10 μm on the glass plate.

The obtained polyimide film was peeled from the glass plate, and each of the properties was measured. The results are shown in Table 1.

### Example 2

In a 500 mL (internal volume) glass reaction vessel equipped with a stirrer and a nitrogen-gas charging/discharging tube was placed 420 g of N-methyl-2-pyrrolidone as a solvent. Then 16.1910 g (0.0809 mol) of ODA, 12.0734 g (0.0347 mol) of BAFL, 11.0990 g (0.0289 mol) of CpODA, 40.5803 g (0.0866 mol) of HTAC(PPD) and 1.1105 g (0.0116 mol) of 1,2-DMZ were added thereto, and the mixture was stirred at 50° C., to obtain a polyamic acid solution having a solid content of 15.17%.

A polyimide film was formed in the same way as in Example 1 except that this polyamic acid solution was used, and each of the properties was measured. The results are shown in Table 1.

### Example 31

In a 500 mL (internal volume) glass reaction vessel equipped with a stirrer and a nitrogen-gas charging/discharging tube was placed 420 g of N-methyl-2-pyrrolidone as a solvent. Then 19.5454 g (0.0976 mol) of ODA, 8.5019 g (0.0244 mol) of BAFL, 23.4472 g (0.0610 mol) of CpODA and 28.5761 g (0.0610 mol) of HTAC(PPD) were added thereto, and the mixture was stirred at 50° C., to obtain a polyamic acid solution having a solid content of 15.12%.

A polyimide film was formed in the same way as in Example 1 except that this polyamic acid solution was used, and each of the properties was measured. The results are shown in Table 1.

### Example 4

In a 500 mL (internal volume) glass reaction vessel equipped with a stirrer and a nitrogen-gas charging/discharging tube was placed 420 g of N-methyl-2-pyrrolidone as a solvent. Then 20.8270 g (0.1040 mol) of ODA, 9.0594 g (0.0260 mol) of BAFL, 19.6482 g (0.0650 mol) of DNDA and 30.4499 g (0.0650 mol) of HTAC(PPD) were added thereto, and the mixture was stirred at 50° C., to obtain a polyamic acid solution having a solid content of 15.06%.

A polyimide film was formed in the same way as in Example 1 except that this polyamic acid solution was used, and each of the properties was measured. The results are shown in Table 1.

### Example 5

In a 500 mL (internal volume) glass reaction vessel equipped with a stirrer and a nitrogen-gas charging/discharging tube was placed 420 g of N-methyl-2-pyrrolidone as a solvent. Then 22.2208 g (0.1110 mol) of ODA, 9.6657 g (0.0277 mol) of BAFL, 15.5462 g (0.0694 mol) of H-PMDA and 32.4877 g (0.0694 mol) of HTAC(PPD) were added thereto, and the mixture was stirred at 50° C., to obtain a polyamic acid solution having a solid content of 14.99%.

A polyimide film was formed in the same way as in Example 1 except that this polyamic acid solution was used, and each of the properties was measured. The results are shown in Table 1.

### Example 6

In a 500 mL (internal volume) glass reaction vessel equipped with a stirrer and a nitrogen-gas charging/discharging tube was placed 420 g of N-methyl-2-pyrrolidone as a solvent. Then 22.7816 g (0.1138 mol) of ODA, 9.9096 g (0.0284 mol) of BAFL, 13.9434 g (0.0711 mol) of CBDA and 33.3075 g (0.0711 mol) of HTAC(PPD) were added thereto, and the mixture was stirred at 50° C., to obtain a polyamic acid solution having a solid content of 14.97%.

A polyimide film was formed in the same way as in Example 1 except that this polyamic acid solution was used, and each of the properties was measured. The results are shown in Table 1. [0065]1

### Example 7

In a 500 mL (internal volume) glass reaction vessel equipped with a stirrer and a nitrogen-gas charging/discharging tube was placed 420 g of N-methyl-2-pyrrolidone as a solvent. Then 22.2689 g (0.1112 mol) of ODA, 9.6866 g (0.0278 mol) of BAFL, 26.7144 g (0.0695 mol) of CpODA and 21.2885 g (0.0695 mol) of H-BPDA were added thereto, and the mixture was stirred at 50° C., to obtain a polyamic acid solution having a solid content of 15.00%.

A polyimide film was formed in the same way as in Example 1 except that this polyamic acid solution was used, and each of the properties was measured. The results are shown in Table 1.

### Example 8

In a 500 mL (internal volume) glass reaction vessel equipped with a stirrer and a nitrogen-gas charging/discharging tube was placed 420 g of N-methyl-2-pyrrolidone as a solvent. Then 25.4806 g (0.0692 mol) of BAPB, 10.3278 g (0.0296 mol) of BAFL, 9.4942 g (0.0247 mol) of CpODA and 34.7129 g (0.0741 mol) of HTAC(PPD) were added thereto, and the mixture was stirred at 50° C., to obtain a polyamic acid solution having a solid content of 15.29%.

A polyimide film was formed in the same way as in Example 1 except that this polyamic acid solution was used, and each of the properties was measured. The results are shown in Table 2.

### Example 9

In a 500 mL (internal volume) glass reaction vessel equipped with a stirrer and a nitrogen-gas charging/discharging tube was placed 420 g of N-methyl-2-pyrrolidone as a solvent. Then 25.4806 g (0.0692 mol) of BAPB, 10.3278 g (0.0296 mol) of BAFL, 9.4942 g (0.0247 mol) of CpODA, 34.7129 g (0.0741 mol) of HTAC(PPD) and 0.9500 g (0.0099 mol) of 1,2-DMZ were added thereto, and the mixture was stirred at 50° C., to obtain a polyamic acid solution having a solid content of 15.29%.

A polyimide film was formed in the same way as in Example 1 except that this polyamic acid solution was used, and each of the properties was measured. The results are shown in Table 2.

### Example 10

In a 500 mL (internal volume) glass reaction vessel equipped with a stirrer and a nitrogen-gas charging/discharging tube was placed 420 g of N-methyl-2-pyrrolidone as a solvent. Then 26.8733 g (0.0729 mol) of BAPB, 10.8922 g (0.0313 mol) of BAFL, 30.0393 g (0.0782 mol) of CpODA and 12.2034 g (0.0261 mol) of HTAC(PPD) were added thereto, and the mixture was stirred at 50° C., to obtain a polyamic acid solution having a solid content of 15.25%.

A polyimide film was formed in the same way as in Example 1 except that this polyamic acid solution was used, and each of the properties was measured. The results are shown in Table 2.

### Example 11

In a 500 mL (internal volume) glass reaction vessel equipped with a stirrer and a nitrogen-gas charging/discharging tube was placed 420 g of N-methyl-2-pyrrolidone as a solvent. Then 26.8733 g (0.0729 mol) of BAPB, 10.8922 g (0.0313 mol) of BAFL, 30.0393 g (0.0782 mol) of CpODA, 12.2034 g (0.0261 mol) of HTAC(PPD) and 1.0019 g (0.0104 mol) of 1,2-DMZ were added thereto, and the mixture was stirred at 50° C., to obtain a polyamic acid solution having a solid content of 15.25%.

A polyimide film was formed in the same way as in Example 1 except that this polyamic acid solution was used, and each of the properties was measured. The results are shown in Table 2.

### Example 12

In a 500 mL (internal volume) glass reaction vessel equipped with a stirrer and a nitrogen-gas charging/discharging tube was placed 420 g of N-methyl-2-pyrrolidone as a solvent. Then 29.1944 g (0.0792 mol) of BAPB, 11.8339 g (0.0340 mol) of BAFL, 25.6636 g (0.0849 mol) of DNDA, 13.2574 g (0.0283 mol) of HTAC(PPD) and 1.0884 g (0.0113 mol) of 1,2-DMZ were added thereto, and the mixture was stirred at 50° C., to obtain a polyamic acid solution having a solid content of 15.18%.

A polyimide film was formed in the same way as in Example 1 except that this polyamic acid solution was used, and each of the properties was measured. The results are shown in Table 2.

### Example 131

In a 500 mL (internal volume) glass reaction vessel equipped with a stirrer and a nitrogen-gas charging/discharging tube was placed 420 g of N-methyl-2-pyrrolidone as a solvent. Then 12.7165 g (0.0635 mol) of ODA, 8.8504 g (0.0254 mol) of BAFL, 4.3506 g (0.0381 mol) of CHDA, 24.4081 g (0.0635 mol) of CpODA and 29.7472 g (0.0635 mol) of HTAC(PPD) were added thereto, and the mixture was stirred at 50° C., to obtain a polyamic acid solution having a solid content of 15.09%.

A polyimide film was formed in the same way as in Example 1 except that this polyamic acid solution was used, and each of the properties was measured. The results are shown in Table 2.

### Example 14

In a 500 mL (internal volume) glass reaction vessel equipped with a stirrer and a nitrogen-gas charging/discharging tube was placed 420 g of N-methyl-2-pyrrolidone as a solvent. Then 12.7165 g (0.0635 mol) of ODA, 8.8504 g (0.0254 mol) of BAFL, 4.3506 g (0.0381 mol) of CHDA, 24.4081 g (0.0635 mol) of CpODA, 29.7472 g (0.0635 mol) of HTAC(PPD) and 1.2211 g (0.0127 mol) of 1,2-DMZ were added thereto, and the mixture was stirred at 50° C., to obtain a polyamic acid solution having a solid content of 15.09%.

A polyimide film was formed in the same way as in Example 1 except that this polyamic acid solution was used, and each of the properties was measured. The results are shown in Table 2.

### Example 15

In a 500 mL (internal volume) glass reaction vessel equipped with a stirrer and a nitrogen-gas charging/discharging tube was placed 420 g of N-methyl-2-pyrrolidone as a solvent. Then 20.6338 g (0.0560 mol) of BAPB, 7.8051 g (0.0224 mol) of BAFL, 3.8368 g (0.0336 mol) of CHDA, 21.5253 g (0.0560 mol) of CpODA and 26.2338 g (0.0560 mol) of HTAC(PPD) were added thereto, and the mixture was stirred at 50° C., to obtain a polyamic acid solution having a solid content of 15.19%.

A polyimide film was formed in the same way as in Example 1 except that this polyamic acid solution was used, and each of the properties was measured. The results are shown in Table 2.

### Example 16

In a 500 mL (internal volume) glass reaction vessel equipped with a stirrer and a nitrogen-gas charging/discharging tube was placed 420 g of N-methyl-2-pyrrolidone as a solvent. Then 16.5499 g (0.0450 mol) of BAPB, 11.7389 g (0.0337 mol) of BAFL, 3.8471 g (0.0337 mol) of CHDA, 21.5829 g (0.0562 mol) of CpODA, 26.3040 g (0.0562 mol) of HTAC(PPD) and 1.0798 g (0.0112 mol) of 1,2-DMZ were added thereto, and the mixture was stirred at 50° C., to obtain a polyamic acid solution having a solid content of 15.19%.

A polyimide film was formed in the same way as in Example 1 except that this polyamic acid solution was used, and each of the properties was measured. The results are shown in Table 2. [0085]1

### Example 171

In a 500 mL (internal volume) glass reaction vessel equipped with a stirrer and a nitrogen-gas charging/discharging tube was placed 420 g of N-methyl-2-pyrrolidone as a solvent. Then 18.7162 g (0.0508 mol) of BAPB, 13.2756 g (0.0381 mol) of BAFL, 4.3506 g (0.0381 mol) of CHDA, 28.7922 g (0.0953 mol) of DNDA, 14.8736 g (0.0318 mol) of HTAC(PPD) and 1.2211 g (0.0127 mol) of 1,2-DMZ were added thereto, and the mixture was stirred at 50° C., to obtain a polyamic acid solution having a solid content of 15.08%.

A polyimide film was formed in the same way as in Example 1 except that this polyamic acid solution was used, and each of the properties was measured. The results are shown in Table 2.

### Example 181

In a 500 mL (internal volume) glass reaction vessel equipped with a stirrer and a nitrogen-gas charging/discharging tube was placed 420 g of N-methyl-2-pyrrolidone as a solvent. Then 26.8733 g (0.0729 mol) of BAPB, 10.8922 g (0.0313 mol) of BAFL, 30.0393 g (0.0782 mol) of CpODA, 12.2034 g (0.0261 mol) of HTAC(PPD) and 1.0019 g (0.0104 mol) of 1,2-DMZ were added thereto, and the mixture was stirred at 50° C., to obtain a polyamic acid solution having a solid content of 15.25%. Subsequently, the polyamic acid solution was heated at 200° C. for 2 hours, to imidize the polyamic acid and obtain a polyimide solution.

A polyimide film was formed in the same way as in Example 1 except that this polyimide solution was used, and each of the properties was measured. The results are shown in Table 2.

### Comparative Example 1

In a 500 mL (internal volume) glass reaction vessel equipped with a stirrer and a nitrogen-gas charging/discharging tube was placed 420 g of N-methyl-2-pyrrolidone as a solvent. Then 18.3438 g (0.0916 mol) of ODA, 7.9793 g (0.0229 mol) of BAFL and 53.6387 g (0.1145 mol) of HTAC(PPD) were added thereto, and the mixture was stirred at 50° C., to obtain a polyamic acid solution having a solid content of 15.17%.

A polyimide film was formed in the same way as in Example 1 except that this polyamic acid solution was used, and each of the properties was measured. The results are shown in Table 1.

### Comparative Example 2

In a 500 mL (internal volume) glass reaction vessel equipped with a stirrer and a nitrogen-gas charging/discharging tube was placed 420 g of N-methyl-2-pyrrolidone as a solvent. Then 20.8751 g (0.1042 mol) of ODA, 9.0803 g (0.0261 mol) of BAFL and 50.0847 g (0.1303 mol) of CpODA were added thereto, and the mixture was stirred at 50° C., to obtain a polyamic acid solution having a solid content of 15.06%.

A polyimide film was formed in the same way as in Example 1 except that this polyamic acid solution was used, and each of the properties was measured. The results are shown in Table 1.

TABLE 1

| | | | Exam- | Exam- | Exam- | Exam- | Exam- | Exam- | Exam- | Comparative | Comparative |
|---|---|---|---|---|---|---|---|---|---|---|---|
| | | | ple 1 | ple 2 | ple 3 | ple 4 | ple 5 | ple 6 | ple 7 | Example 1 | Example 2 |
| polyamic acid (molar ratio) | | | | | | | | | | | |
| tetracarboxylic | a₁ | HTAC (PPD) | 75 | 75 | 50 | 50 | 50 | 50 | | 100 | |
| dianhydride | | H-BPDA | | | | | | | 50 | | |
| | a₂ | CpODA | 25 | 25 | 50 | | | | 50 | | 100 |
| | | DNDA | | | | 50 | | | | | |
| | | H-PMDA | | | | | 50 | | | | |
| | | CBDA | | | | | | 50 | | | |

| | | | | | | | | | | |
|---|---|---|---|---|---|---|---|---|---|---|
| diamine | BAFL | 30 | 30 | 20 | 20 | 20 | 20 | 20 | 20 | 20 |
| | ODA | 70 | 70 | 80 | 80 | 80 | 80 | 80 | 80 | 80 |
| | CHDA | | | | | | | | | |
| | BAPB | | | | | | | | | |
| catalyst | 1,2-DMZ | | 10 | | | | | | | |

| | | | | | | | | | |
|---|---|---|---|---|---|---|---|---|---|
| polyimide film | | | | | | | | | |
| film thickness (μm) | 10.0 | 10.0 | 10.0 | 10.0 | 10.0 | 10.0 | 10.0 | 10.0 | 10.0 |
| transmittance @ 400 nm (%) | 83 | 82 | 85 | 87 | 85 | 83 | 88 | 83 | 87 |
| transmittance @ 365 nm (%) | 78 | 76 | 81 | 83 | 79 | 77 | 85 | 72 | 83 |
| elongation (%) | 25 | 39 | 13 | 15 | 44 | 27 | 63 | 66 | 2 |
| Rth (590 nm) (nm) | 0 | 0 | 4 | 0 | 11 | 2 | 2 | 21 | 23 |
| Tg (□) | 330 | 329 | 340 | 350 | 320 | 342 | 342 | 299 | 364 |

TABLE 2

| | | | | | Exam- | Exam- | Exam- | Exam- | Exam- | Exam- | Exam- | Exam- | Exam- |
|---|---|---|---|---|---|---|---|---|---|---|---|---|---|
| | | | Exam- | Exam- | ple | ple | ple | ple | ple | ple | ple | ple | ple |
| | | | ple 8 | ple 9 | 10 | 11 | 12 | 13 | 14 | 15 | 16 | 17 | 18 |
| polyamic acid (molar ratio) | | | | | | | | | | | | | |
| tetracarboxylic | a₁ | HTAC | 75 | 75 | 25 | 25 | 25 | 50 | 50 | 50 | 50 | 25 | 25 |
| dianhydride | | (PPD) | | | | | | | | | | | |
| | | H-BPDA | | | | | | | | | | | |
| | a₂ | CpODA | 25 | 25 | 75 | 75 | | 50 | 50 | 50 | 50 | | 75 |
| | | DNDA | | | | | 75 | | | | | 75 | |
| | | H-PMDA | | | | | | | | | | | |
| | | CBDA | | | | | | | | | | | |

| | | | | | | | | | | | | |
|---|---|---|---|---|---|---|---|---|---|---|---|---|
| diamine | BAFL | 30 | 30 | 30 | 30 | 30 | 20 | 20 | 20 | 30 | 30 | 30 |
| | ODA | | | | | | 50 | 50 | | | | |
| | CHDA | | | | | | 30 | 30 | 30 | 30 | 30 | |
| | BAPB | 70 | 70 | 70 | 70 | 70 | | | 50 | 40 | 40 | 70 |
| catalyst | 1,2-DMZ | | 10 | | 10 | 10 | | 10 | | 10 | 10 | 10 |

| | | | | | | | | | | | |
|---|---|---|---|---|---|---|---|---|---|---|---|
| polyimide film | | | | | | | | | | | |
| film thickness (μm) | 10.0 | 10.0 | 10.0 | 10.0 | 10.0 | 10.0 | 10.0 | 10.0 | 10.0 | 10.0 | 10.0 |
| transmittance @ 400 nm (%) | 81 | 85 | 79 | 84 | 84 | 86 | 86 | 86 | 84 | 85 | 86 |
| transmittance @ 365 nm (%) | 72 | 82 | 85 | 87 | 78 | 84 | 81 | 84 | 76 | 79 | 82 |
| elongation (%) | 41 | 57 | 18 | 27 | 29 | 16 | 28 | 39 | 14 | 14 | 40 |
| Rth (590 nm) (nm) | 5 | 4 | 12 | 16 | 11 | 16 | 41 | 13 | 7 | 29 | 82 |
| Tg (□) | 307 | 314 | 342 | 352 | 361 | 350 | 352 | 342 | 348 | 383 | 353 |

1. A polyamic acid solution composition, comprising a polyamic acid obtained by reacting a tetracarboxylic acid component and a diamine component, and a solvent, wherein
the tetracarboxylic acid component consists of one or more tetracarboxylic dianhydride (a₁), wherein at least one of the bonds linking the two cyclic anhydride structures contained in the molecule is a freely rotatable bond and a phthalic anhydride structure is not contained therein, and one or more tetracarboxylic dianhydride (a₂) having an alicyclic structure, wherein each of two cyclic anhydride structures shares at least one carbon-carbon bond with the alicyclic structure and a freely rotatable bond is not contained in the molecule; and
the diamine component comprises one or more diamine having a 9,9-diphenylfluorene structure in an amount of 5 to 50 mol %.

2. The polyamic acid solution composition according to claim 1, wherein the tetracarboxylic dianhydride (a₁) has 8 to 50 carbon atoms, and the tetracarboxylic dianhydride (a₂) has 8 to 30 carbon atoms.

3. The polyamic acid solution composition according to claim 1, wherein the tetracarboxylic dianhydride (a₁) is a compound selected from 1,2,3,4-butane tetracarboxylic dianhydride, 4-(2,5-dioxotetrahydrofuran-3-yl)-1,2,3,4-tetrahydronaphthalene-1,2-dicarboxylic anhydride, dicyclohexyl-3,3′,4,4′-tetracarboxylic dianhydride, N,N′-(1,4-phenylene)bis(1,3-dioxooctahydroisobenzofuran-5-carboxyamide), and N,N′-(oxybis(1,4-phenylene))bis(1,3-dioxooctahydroisobenzofuran-5-carboxyamide).

4. The polyamic acid solution composition according to claim 1, wherein the tetracarboxylic dianhydride (a₂) is a compound selected from 1,2,3,4-cyclobutane tetracarboxylic dianhydride, 1,2,4,5-cyclohexane tetracarboxylic dianhydride, norbornane-2-spiro-α-cyclopentanone-α′-spiro-2″-norborane-5,5″,6,6″-tetracarboxylic dianhydride, and decahydro-1,4:5,8-dimethanonaphthalene-2,3,6,7-tetracarboxylic dianhydride.

5. A method for producing a flexible device, comprising steps of:
applying the polyamic acid solution composition according to claim 1 on a carrier substrate, and then heating the composition to form a polyimide film on the carrier substrate;
forming a circuit on the polyimide film; and
peeling the polyimide film having the circuit formed on the surface from the carrier substrate.

6. A polyimide film consisting essentially of a polyimide obtained by polymerizing a tetracarboxylic acid component and a diamine component, wherein
the tetracarboxylic acid component consists of one or more tetracarboxylic dianhydride (a₁), wherein at least one of the bonds linking the two cyclic anhydride structures contained in the molecule is a freely rotatable bond and a phthalic anhydride structure is not contained therein, and one or more tetracarboxylic dianhydride (a₂) having an alicyclic structure, wherein each of two cyclic anhydride structures shares at least one carbon-carbon bond with the alicyclic structure and a freely rotatable bond is not contained in the molecule; and
the diamine component comprises one or more diamine having a 9,9-diphenylfluorene structure in an amount of 5 to 50 mol %.

7. The polyimide film according to claim 6, wherein the tetracarboxylic dianhydride (a₁) has 8 to 50 carbon atoms, and the tetracarboxylic dianhydride (a₂) has 8 to 30 carbon atoms.

8. The polyimide film according to claim 6, wherein the tetracarboxylic dianhydride (a₁) is a compound selected from 1,2,3,4-butane tetracarboxylic dianhydride, 4-(2,5-dioxotetrahydrofuran-3-yl)-1,2,3,4-tetrahydronaphthalene-1,2-dicarboxylic anhydride, dicyclohexyl-3,3′,4,4′-tetracarboxylic dianhydride, N,N′-(1,4-phenylene)bis(1,3-dioxooctahydroisobenzofuran-5-carboxyamide), and N,N′-(oxybis(1,4-phenylene))bis(1,3-dioxooctahydroisobenzofuran-5-carboxyamide).

9. The polyimide film according to claim 6, wherein the tetracarboxylic dianhydride (a₂) is a compound selected from 1,2,3,4-cyclobutane tetracarboxylic dianhydride, 1,2,4,5-cyclohexane tetracarboxylic dianhydride, norbornane-2-spiro-α-cyclopentanone-α′-spiro-2″-norbornane-5,5″,6,6″-tetracarboxylic dianhydride, and decahydro-1,4:5,8-dimethanonaphthalene-2,3,6,7-tetracarboxylic dianhydride.

10. The polyimide film according to claim 6, wherein
the glass-transition temperature (Tg) is 300° C. or higher;
the elongation is 10% or more; and
the retardation in the thickness direction (Rth) is 100 nm or less.

11. A flexible device, comprising the polyimide film according to claim 6 as a substrate.
